(19) United States
(12) Patent Application Publication
(10) Pub. No.: US 2008/0296660 A1
(43) Pub. Date: Dec. 4, 2008

(54) LOW RESISTIVITY CONDUCTIVE STRUCTURES, DEVICES AND SYSTEMS INCLUDING SAME, AND METHODS FORMING SAME

(75) Inventors: Jinho PARK, Gyeonggi-do (KR); Sang-Woo LEE, Seoul (KR); Ho-Ki LEE, Gyeonggi-do (KR); Gilheyun CHOI, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/947,006

(22) Filed: Nov. 29, 2007

(30) Foreign Application Priority Data
Jun. 1, 2007 (KR) 2007-0053855

(51) Int. Cl. H01L 29/00; C23C 16/00; B32B 7/02

(52) U.S. Cl. 257/324; 427/250; 428/212; 257/E29.3

(57) ABSTRACT

A conductive structure and method for making same is disclosed and includes a first nucleation layer formed by performing a cyclic deposition process on a substrate, a second nucleation layer formed on the first nucleation layer by a CVD process, and a bulk metal layer formed on the second nucleation layer.

### CROSS-REFERENCE TO RELATED APPLICATIONS

This application claims priority to Korean Patent Application No. 2007-0053855 filed on Jun. 1, 2007, the subject matter of which is hereby incorporated by reference.

### BACKGROUND OF THE INVENTION

1. Field of the Invention

Embodiments of the invention relate generally to various conductive structures in electronic devices. More particularly, embodiments of the invention relate to low resistivity conductive structures including a bulk metal layer, devices and systems including same, methods of forming same, and systems capable of fabricating same.

2. Description of Related Art

Recent efforts to increase the speed and integration density of contemporary electronic devices have resulted in increased performance and quality demands on conductive structures, such as line interconnections, contacts, electrode structures, etc., within these devices. For example, as the switching rate for signals within an electronic device increase and the average size of the individual elements forming the device decrease, the geometry, morphology, and electrical resistance properties of various conductive structures within the device become increasingly important. Such characteristics must be carefully considered in order to avoid the possibility of signal corruption, undesired signal delays, data errors, excess heat dissipation, and so on. In addition, as the average size of individual elements forming the device decreases, an increasingly limited range of fabrication variations can be tolerated, since increasingly small physical defects or process deviations can cause more significant problems in devices and systems implemented with elements having very small geometries.

In general, the performance of a conductive structure is a function of its electrical impedance, and electrical impedance is a function of resistance or unit area resistivity. For example, as the electrical resistance of a conductive structure increases, its immunity to signal noise decreases. The conductive structure also tends to dissipate more heat during signal transmission, and overall electron mobility through the conductive structure tends to decrease.

Broadly speaking, the electrical resistance of a conductive structure is a function of its geometry and resistivity properties. In particular, as the conductive structure's length increases or its cross-sectional area decreases, its resistance tends to increase proportionally. Similarly, as a conductive structure's resistivity increases, its overall resistance and impedance also increase.

Due to increasing integration density requirements for contemporary electronic devices, the size of individual conductive structures must be reduced to accommodate an increasingly limited chip area. As a result, conductive structures like patterned signal lines within contemporary electronic devise are becoming increasingly thin and narrow. Other conductive structures like contacts are becoming increasingly small and more closely grouped. In order to compensate for these changes in geometry, certain low-resistivity materials such as tungsten (W) are commonly used to form conductive structures. For example, contemporary memory devices, and flash memory devices in particular, commonly include bit lines formed from one or more material layers including tungsten.

Unfortunately, conventional methods of forming bulk metal layers, including bulk metal layers including tungsten, suffer from a variety of shortcomings that have hindered the realization of conductive structures of desired geometry and sufficient performance.

In recent attempts to improve the performance of conductive structures having reduced geometries, certain nucleation processes have been used. It was hoped that material layers formed by various nucleation processes would allow for the fabrication of thinner, more narrow, and/or smaller conductive structures having adequate resistivity properties.

However, some nucleation layers, such as those formed by various cyclical deposition methods, while exhibiting good uniformity in nuclei distribution, also exhibit relatively high resistivity. In contrast, other nucleation layers, such as those formed by chemical vapor disposition (CVD) methods, exhibit marginally better resistivity properties, but suffer from poor nuclei distribution uniformity. As a result, it remains difficult to fabricate small geometry conduct structures from bulk metal layers which have acceptable aggregate performance qualities.

### SUMMARY OF THE INVENTION

Embodiments of the invention provide low-resistivity conductive structures including bulk metal layers, methods of forming same, devices and systems including same, and fabrication systems for making same. In selected embodiments of the invention, the bulk metal layer is formed with relatively large material grains having uniformly distributed nuclei, as compared with bulk metal layers formed using conventional techniques.

In one embodiment, the invention provides a method of forming a conductive structure, comprising; forming a first nucleation layer on a substrate using a cyclic deposition process, forming a second nucleation layer on the first nucleation layer using a chemical vapor deposition (CVD) process, and forming a bulk metal layer on the second nucleation layer.

In another embodiment, the invention provides a conductive structure, comprising; a first nucleation layer formed on a substrate and having a first material grain size, a second nucleation layer formed on the first nucleation layer and having a second material grain size larger than the first material grain size, and a bulk metal layer formed on the second nucleation layer.

In another embodiment, the invention provides a transistor, comprising; a gate structure formed on a substrate, and opposing source/drain regions formed in the substrate on either side of the gate structure. The gate structure includes a gate electrode comprising; a patterned first nucleation layer formed on the substrate and having a first material grain size, a patterned second nucleation layer having a second material grain size larger than the first material grain size and formed on the patterned first nucleation layer, and a patterned bulk metal layer formed on the patterned second nucleation layer.

In one related aspect, the transistor further comprises; a patterned gate insulating layer formed on the substrate, a patterned polysilicon layer formed on the pattern gated insulating layer, and a patterned conductive layer formed on the patterned polysilicon layer, wherein the patterned first nucleation layer is formed on the patterned conductive layer. In another related aspect, the transistor further comprises a patterned insulating layer formed on the substrate, a patterned charge storing layer formed on the pattern insulating layer, a patterned blocking insulating layer formed on the patterned charge storing layer, and a patterned conductive layer formed on the patterned blocking insulating layer, wherein the patterned first nucleation layer is formed on the patterned conductive layer.

In another embodiment, the invention provides a method of forming a conductive structure on a substrate entirely within a single process chamber comprising a plurality of process chamber regions segregated from one another by at least one air curtain, the method comprising; loading the substrate onto a first heater chuck disposed in a first process chamber region, forming a first nucleation layer on the substrate by performing a cyclic deposition process in the first process chamber, transferring the wafer through the air curtain from the first process chamber region to a second heater chuck disposed in a second process chamber region using a wafer transfer unit centrally located in the process chamber, forming a second nucleation layer on the first nucleation layer by performing a chemical vapor disposition (CVD) process in the second process chamber region, and forming a bulk metal layer comprising tungsten on the second nucleation layer.

### BRIEF DESCRIPTION OF THE DRAWINGS

Embodiments of the invention are described below with reference to the accompanying drawings. Throughout the drawings like reference labels indicate like or similar features. In the drawings:

FIGS. 1A through 1C are related schematic diagrams illustrating a method of forming a conductive structure including a bulk metal layer in accordance with an embodiment of the invention;

FIG. 2A is a general flowchart summarizing the method illustrated in FIGS. 1A through 1C;

FIG. 2B is a conceptual timing diagram related to the method of FIG. 2A;

FIG. 3 is a flowchart summarizing the process of forming the first nucleation layer within the context of the method illustrated in FIGS. 1A through 1C, and FIG. 2;

FIGS. 4A through 4D are related schematic diagrams illustrating a method of forming a line pattern in accordance with an embodiment of the invention;

FIGS. 5A and 5B are related schematic diagrams illustrating a method of forming a transistor in accordance with an embodiment of the invention;

FIGS. 6A and 6B are schematic diagrams illustrating a conductive structure formed in an opening in accordance with an embodiment of the invention;

FIGS. 7A and 7B are related schematic diagrams illustrating a method of forming a transistor for a nonvolatile memory device in accordance with an embodiment of the invention; and

FIG. 8 is an overhead schematic diagram illustrating a processing apparatus which may be adapted to the fabrication of a conductive structure including a bulk metal layer in accordance with various embodiments of the invention.

### DESCRIPTION OF EMBODIMENTS

Selected embodiments of the invention will be described with reference to the corresponding drawings. These embodiments are presented as teaching examples while the actual scope of the invention is defined by the claims that follow.

In various embodiments of the invention, conductive structures including a bulk metal layer are characterized by relatively low resistivity and a relatively uniform distribution of nuclei within the constituent materials forming the conductive structures. These properties may be obtained in a conductive structure by sequentially forming a first nucleation layer using a cyclic deposition process, a second nucleation layer using a chemical vapor deposition (CVD) process, and then a bulk metal layer.

In certain embodiments of the invention, the first nucleation layer is deposited on a substrate or an underlying material layer using multiple iterations of the cyclic deposition process. The second nucleation layer (and possibly the bulk metal layer as well) may then be deposited on the first nucleation layer using a CVD process.

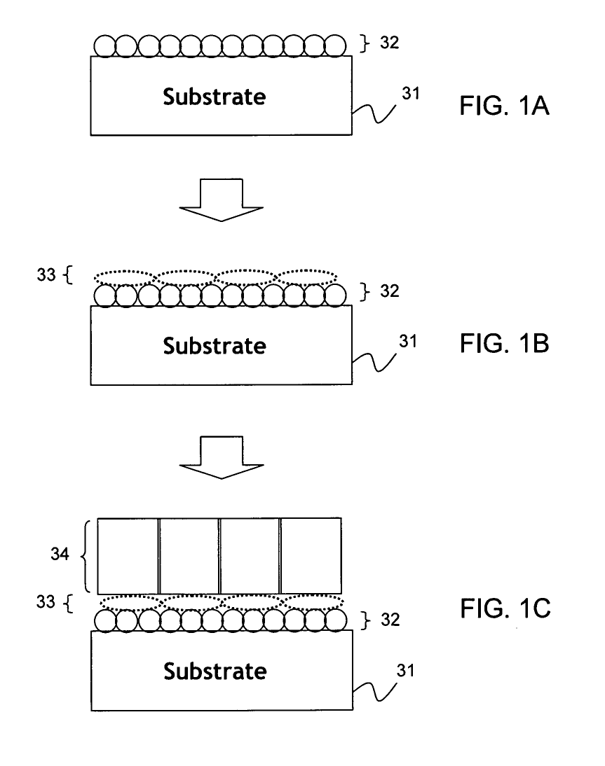

FIGS. 1A through 1C are related schematic diagrams illustrating an exemplary method of forming a conductive structure including a bulk metal layer according to an embodiment of the invention. For explanation purposes, it will be assumed that the bulk metal layer described in FIGS. 1A through 1C is principally composed of tungsten (W) or a tungsten alloy. Hereafter, all references to exemplary metals, including metals forming metal suicides and metal nitrides, will denote conventionally understood alloys as well as the elemental metals. That is, those of ordinary skill in the art understand that both elemental metals and related alloys are useful in the fabrication of conductive elements within electronic devices. Similarly, those skilled in the art will recognize that a variety of different metals and/or metal alloys may be substituted for, or additionally provided with the exemplary metals referenced in the following embodiments.

Referring now to FIG. 1A, a first nucleation layer 32 is formed on a substrate 31 using a cyclic deposition process. At this juncture, it should be noted that the phrase “formed on” may mean “formed directly on”, or “formed on with the presence of one or more intervening layers.” Substrate 31 may be composed of various materials including commonly understood semiconductor materials like silicon, as well as semi-insulating materials like silicon carbide, and/or insulating materials like glass or ceramic. Thus, consistent with the foregoing understanding of the phrase “formed on a substrate 31” means that one or more intervening material layers (e.g., insulating, semi-insulating, or conductive material layer(s)) may be exist between first nucleation layer 32 and substrate 31.

Referring to FIG. 1B, a second nucleation layer 33 is formed on first nucleation layer 32 using a CVD process. As illustrated by FIG. 1B, the presence of first nucleation layer 32 allows second nucleation layer 33 to be formed with a more regular morphology, as compared with conventional nucleation layers formed directly on a substrate. That is, due to certain improved physical interaction properties at the atomic level between the respective nuclei of the material(s) forming first and second nucleation layers 32 and 33, second nucleation layer 33 exhibits a more uniform and predictable morphology following its formation. In contrast, conventional processes attempting to deposit a nucleation layer directly on a substrate using a CVD process often result in a material layer exhibiting a poor morphology (e.g., an uneven and less predictable distribution of nuclei in the material forming the nucleation layer). Poor morphology results from long or highly variable nucleation delays during the CVD process depositing the nucleation material on the substrate. In contrast, second nucleation layer 33 formed by a CVD process in the illustrated embodiment of FIG. 1B exhibits a very good morphology (e.g., a much more uniform distribution of nuclei) because little or no nucleation delay arises during the material formation of second nucleation layer 33 on first nucleation layer 32.

Additionally, and as illustrated in FIG. 1C, the formation of second nucleation layer 33 using a CVD process results in an excellent “wetting layer” of sorts for the subsequently formed bulk metal layer 34 that is characterized by relatively large average material grain size. This increased average material grain size in the wetting layer underlying bulk metal layer 34, the more compatible material boundaries forming the upper surface of the wetting layer, as compared with material layers formed by conventional processes, and the improved morphology of second nucleation layer 33 combine in their effects to reduce the resistivity of the resulting conductive structure including bulk metal layer 34.

Although first nucleation layer 32, second nucleation layers 33, and bulk metal layer 34 are shown in the illustrated embodiment of FIGS. 1A through 1C as being formed directly on each other, certain intermediate processes may alternately be performed between the formation of these layers without impeding the benefits identified above. For example, following the formation of first nucleation layer 32 on substrate 31, one or more plasma treatment process(es) may be performed on first nucleation layer 32 to reduce its surface roughness.

However, although one or more intermediate processes may be performed prior to the formation of first nucleation layer 32, second nucleation layer 33, and/or bulk metal layer 34, it should be noted that at least the uniform morphology exhibited by first nucleation layer 33 and the improved resistivity exhibited by bulk metal layer 34 may be influenced by the physical interactions at the atomic level between material boundaries. Accordingly, any intermediate process performed in relation to the preparation of substrate 31, the formation of first and second nucleation layers 32 and 33, as well as the formation of bulk metal layer 34 should be properly defined and controlled to prevent (or inhibit) the formation of any undesired intermediate material boundaries, contamination layers (e.g., natural oxide layers), and/or surface irregularities that may interfere with the regular formation of first nucleation layer 32 on substrate 31, the formation of second nucleation layer 33 on first nucleation layer 32, and/or the formation of bulk metal layer 34 on second nucleation layer 33.

For example, a surface preparation process, such as a plasma treatment process performed on first nucleation layer 32, should be implemented and controlled in such a manner to avoid disrupting the uniform distribution of nuclei in the material forming second nucleation layer 33.

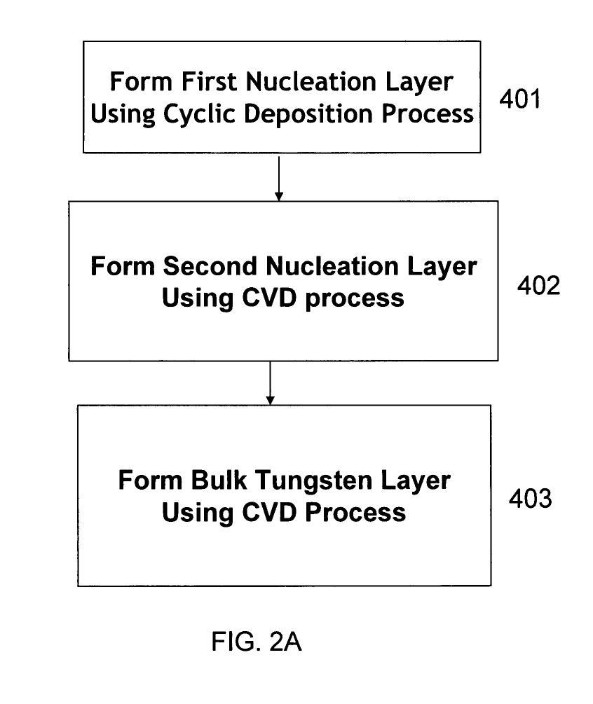

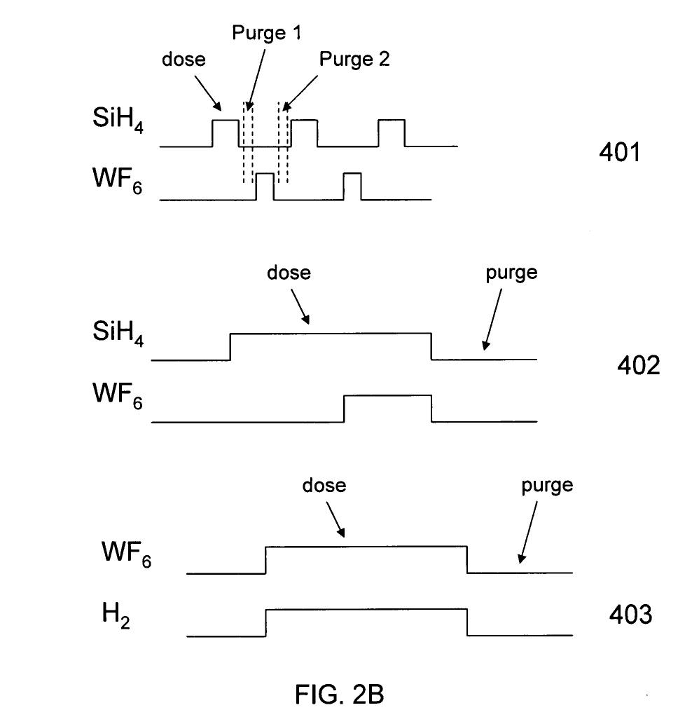

FIG. 2A is a flowchart generally summarizing the method illustrated in FIGS. 1A through 1C. FIG. 2B is a conceptual timing diagram further illustrating the method of FIG. 2A. In the description that follows, exemplary method steps are denoted within parentheses (XXX).

Before explaining FIGS. 2A and 2B, it should be noted that there are many well known processes (or sequence of processes) capable of forming nucleation layers. Cyclic deposition processes and CVD processes are broad subsets of processes that are particularly relevant to the illustrated embodiments presented here. However, those of skilled in the art will recognize that the specific processes described in the context of FIGS. 1A through 1C, 2A and 2B are merely exemplary. They are not intended to provide an exhaustive catalogue of all possible processes (or even all cyclic deposition processes and/or all CVD processes) that might be used. For example, other possible processes include Pulsed Nucleation Layer (PNL) processes, and Atomic Layer Deposition (ALD) processes. In certain embodiments of the invention, the processes described in U.S. Pat. No. 7,141,494, the subject matter of which is hereby incorporated by reference, may find application.

Referring collectively to FIGS. 2A and 2B, first nucleation layer 32 is formed on substrate 31 using the cyclic deposition process (401). In one sense, first nucleation layer 32 can be thought of as a subsidiary nucleation layer formed to function as a wetting layer for second nucleation layer 33. One or more deposition cycles may be used to form first nucleation layer 32 to a desired thickness. In certain embodiments of the invention, first nucleation layer 32 will have a thickness ranging from about 5 to 50 Å.

In the example illustrated in FIG. 2B, first nucleation layer 32 is formed by placing substrate 31 into a processing chamber and then performing the one or more deposition cycle(s). In the illustrated example, each cycle of the cyclic deposition process (401) includes supplying a “dose” of silane (SiH₄) to the process chamber during a defined dosing period. Then, the process chamber is purged to remove any residual portion of silane or related by-product gases during a first purge period (Purge 1). Following the first purge period, a dose of tungsten hexafluoride (WF₆) is supplied to the process chamber. Following the dose of tungsten hexafluoride, the process chamber is again purged during a second purge period (Purge 2) to remove any residual tungsten hexafluoride and/or any by-product gases from the process chamber.

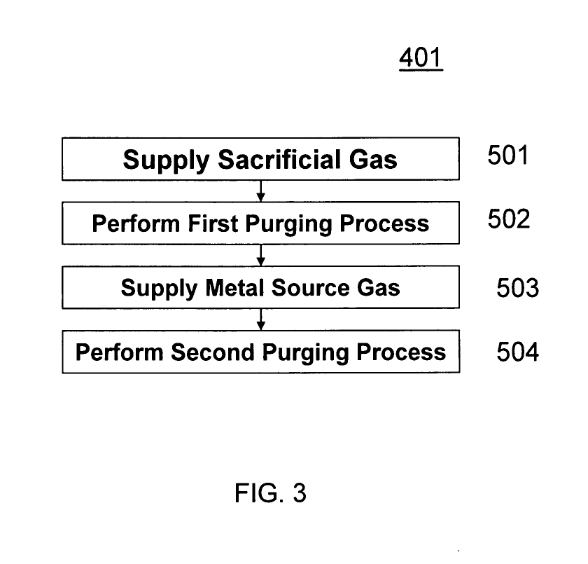

FIG. 3 is a flowchart summarizing a generic cyclic deposition process adapted to the formation of first nucleation layer 32 within the context of the method illustrated by FIG. 2A. In the example of FIG. 3, each one of the deposition cycle(s) is performed by supplying a sacrificial gas to the process chamber containing substrate 31 (501). The sacrificial gas may including one or more gases, and in some embodiments of the invention will include at least one gas including either boron or silicon. Next, a first purging process is performed using one or more inert purging gas(es), such as argon (Ar), to remove any residual portion of the sacrificial gas or by-product gases from the process chamber (502). After the first purging process, a metal source gas is supplied to the process chamber (503). In certain embodiment of the invention, the metal source gas will include at least one gas containing tungsten. Then, a second purging process is performed with inert gas to remove any residual the metal source gas or related by-product gases from the process chamber (504).

Returning to FIGS. 2A and 2B, second nucleation layer 33 is formed on first nucleation layer 303 using a CVD process (402). In certain embodiments of the invention, second nucleation layer 33 is formed to a thickness ranging between about 50 to 300 Å. As described above, second nucleation layer 33 may be formed using one or more processes selected from a variety of different conventional processes, but in one embodiment a CVD process is used.

As illustrated in FIG. 2B, in one embodiment of the invention, second nucleation layer 33 is formed by reacting a metal source gas with a sacrificial gas. For example, to form second nucleation layer 33, tungsten hexafluoride (WF₆) may be used as the metal source gas and a boron or silicon containing gas may be used as the sacrificial gas. Under these assumptions, the sacrificial gas may comprise diborane (B₂H₆), silane (SiH₄), or disilane (Si₂H₆), etc. In certain embodiments of the invention consistent with the foregoing assumptions, the metal gas and the sacrificial gas may be reacted at a temperature ranging from about 250° to 450° C. at a pressure ranging from about 3 to 400 Torr.

In the specific embodiment illustrated in FIG. 2B, second nucleation layer 33 is formed by supplying a dose of silane (SiH₄) to the process chamber during a defined dosing period. During this defined dosing period, a dose of tungsten hexafluoride (WF₆) is provided to the process chamber.

However specifically formed from a process context, second nucleation layer 33 should be characterized by a larger average material grain size than first nucleation layer 32. Accordingly, the ultimate conductive structure including bulk metal layer 34 formed on second nucleation layer 33 will exhibit relatively low resistivity and good morphology.

Returning again to FIGS. 2A and 2B, bulk tungsten layer 34 is formed on second nucleation layer 33 (403). In certain embodiments of the invention, bulk tungsten layer 34 is formed on second nucleation layer 33 using a CVD process. As further illustrated in FIG. 2B, bulk tungsten layer 34 is formed by simultaneously supplying tungsten hexafluoride and diatomic hydrogen (H₂) to the process chamber until bulk tungsten layer 34 is formed to a desired thickness. Selected additional processes for forming a bulk metal layer are disclosed, for example, in U.S. Pat. No. 7,141,494. However, the set of examples provided in U.S. Pat. No. 7,141,494 is not considered exhaustive.

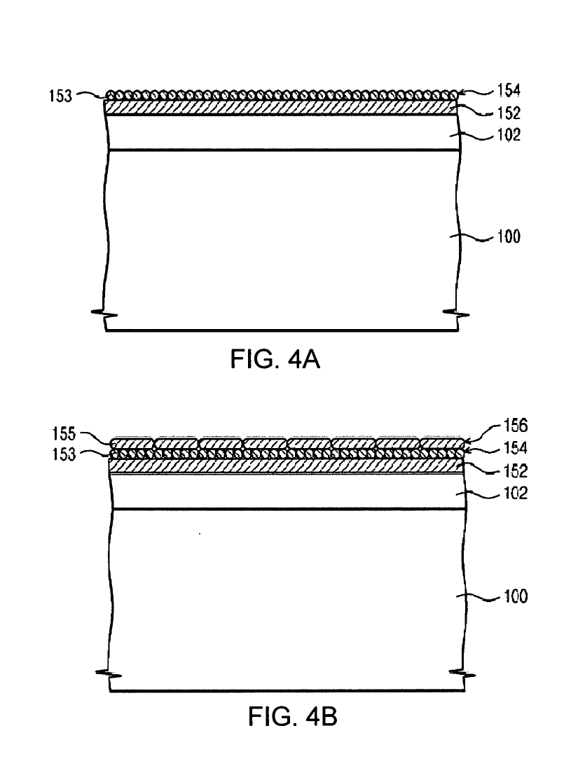

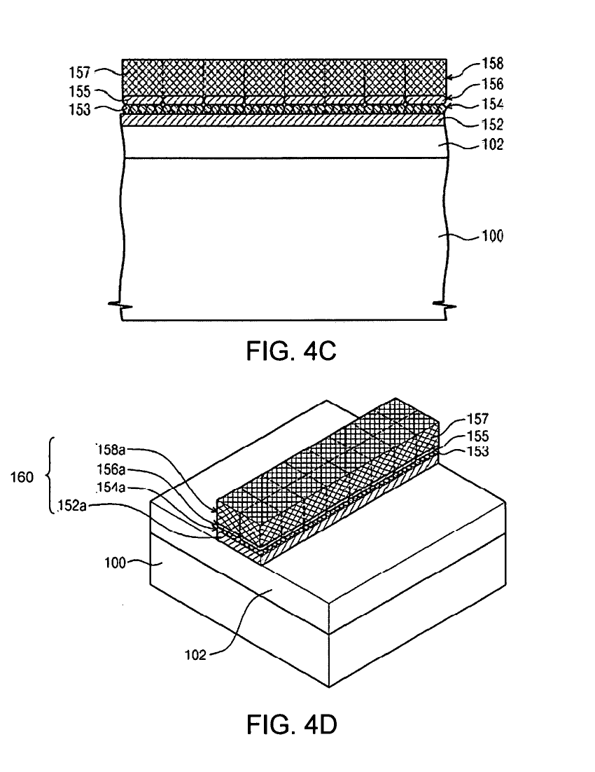

FIGS. 4A through 4C are related schematic diagrams illustrating an exemplary method of forming and patterning a conductive structure including a bulk metal layer consistent with an embodiment of the invention. In the illustrated example, the conductive structure may serve as a signal line pattern. In the method of FIGS. 4A through 4C, a conductive structure including a bulk metal layer may be formed using a method similar to that described above with reference to FIGS. 1A through 1C, FIGS. 2A and 2B, and/or FIG. 3.

Referring to FIG. 4A, an insulating layer 102 is formed on a substrate 100. Next, a conductive layer 152 possibly comprising one or more metal(s) is formed on insulating layer 102. Then, a first nucleation layer 154 is formed on conductive layer 152 using a cyclic deposition process. As illustrated in FIG. 4A, the individual materials grains 153 of first nucleation layer 152 are formed in such a manner that a uniform distribution of material is apparent on the upper surface of conductive layer 152.

Conductive layer 152 may comprise one or more of a wide variety of different metals. For example, conductive layer 152 may comprise a metal nitride, metal silicide, and/or a metal nitride/silicide. Titanium nitride (TiN), tantalum nitride (TaN), tungsten nitride (WN), molybdenum nitride (MoN), niobium nitride (NbN), titanium silicide nitride (TiSiN), tantalum silicide nitride (TaSiN), tungsten silicide (WSix), cobalt silicide (CoSix), and/or nickel silicide (NiSix) are selected examples. Alternately or additionally, elemental metal such as, for example, cobalt (Co), nickel (Ni), platinum (Pt), gold (Au), Iridium (Yr), or Ruthenium (Ru) may be used and/or alloys of same.

Referring to FIG. 4B, a second nucleation layer 156 is formed on first nucleation layer 154. Similar to the material grain pattern 153 of first nucleation layer 154, the individual material grains 155 forming second nucleation layer 156 will have a uniform distribution over the surface of first nucleation layer 154. However, as conceptually illustrated in FIG. 4B, the material grains 155 forming second nucleation layer 156 are significantly larger than the material grains 153 forming first nucleation layer 154.

Referring to FIG. 4C, a bulk metal layer 158 is formed on second nucleation layer 156. In the working example, metal layer 158 is assumed to include tungsten. As seen conceptually in FIG. 4C, bulk metal layer 158 is formed from material grains 157 that are well aligned at their respective boundaries with the material grains 155 forming second nucleation layer 156. As such, bulk metal layer 158 has a relatively large and substantially uniform grain size consistent with second nucleation layer 156, and the overall resistivity of the resulting conductive structure is low.

FIG. 4D is a perspective view further illustrating a line pattern 160 as one example of a conductive structure fabricated according to the method of FIGS. 4A through 4C. In certain more specific embodiments of the invention, line pattern 160 may be incorporated into a semiconductor memory device as a word line and/or a bit line extending across an array of memory cells.

In the context of these more specific embodiments, line pattern 160 may be formed by sequentially patterning bulk metal layer 158, second nucleation layer 156, first nucleation layer 154, and conductive layer 152, until insulating layer 102 is exposed. Such patterning results in the formation of etched bulk metal layer 158a, etched second nucleation layer 156a, etched first nucleation layer 154a, and etched conductive layer 152a. In general, the foregoing material layer patterning may be accomplished with a sequence of conventionally understood photolithography, masking, etching, and cleaning processes. As is well understood by those skilled in the art, different etching processes may be necessary to effectively pattern the different material layers.

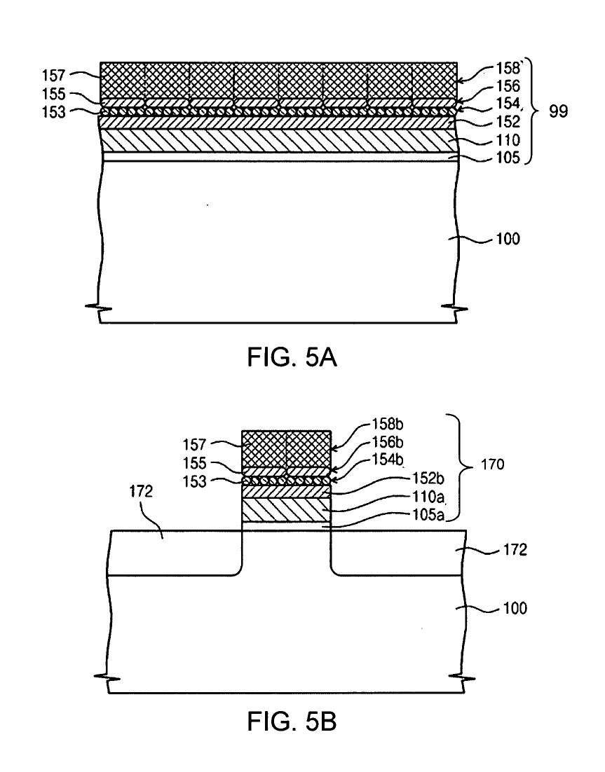

FIGS. 5A and 5B are related schematic diagrams illustrating an exemplary method of forming and patterning a conductive structure including a bulk metal layer within the context of another embodiment of the invention. However, in this embodiment the conductive structure may serve as part (e.g., a gate electrode) of a transistor. The transistor may be one of many different transistor types commonly used in electronic devices. The conductive structure including a bulk metal layer in this embodiment is assumed to be fabricated in accordance with an embodiment of the invention, using for example, the processes, materials, and conditions previously described in the context of FIGS. 1A through 1C, 2A and 2B, 3, and/or 4A through 4B.

In general application, the exemplary transistor is formed to include a gate structure 170 shown in FIG. 5B. Following formation of gate structure 170 including a constituent gate electrode, source/drain regions 172 may be formed in substrate 100 by the selective introduction of dopants (e.g., use of one or more conventional ion implantation processes).

An initial metal layer structure 99 from which gate structure 170 is fabricated is illustrated in FIG. 5A. Initial metal layer structure 99 may be fabricated according to the method previously described in relation to FIGS. 4A through 4C, except that the initial metal layer structure replaces insulating layer 102 with a gate insulating layer 105 and a doped polysilicon layer 110 formed on gate insulating layer 105. Thus, conductive layer 152 in initial metal layer structure 99 is formed on doped polysilicon layer 110.

Referring now to FIG. 5B, gate structure 170 is formed by sequentially patterning bulk metal layer 158, second nucleation layer 156, first nucleation layer 154, conductive layer 152, doped polysilicon layer 110, and gate insulating layer 105. This patterning results in the formation of etched bulk metal layer 158a, etched second nucleation layer 156a, etched first nucleation layer 154a, etched conductive layer 152a, etched doped polysilicon layer 110a, and etched gate insulating layer 105a, on semiconductor substrate 100. Collectively, this stacked arrangements of etched layers constitutes gate structure 170 including a gate electrode. Once gate structure 170 is formed, source/drain regions 172 may be selectively formed in semiconductor substrate 100.

As previously described, those of ordinary skill will understand the selection and application of various photolithography, masking, etching, and cleaning processes to pattern initial metal layer structure 99. The selection and application of these processes will vary with the desired geometry of gate structure 170 and the materials constituting the initial metal layer structure 99.

Those skilled in the art will also recognize that the transistor implemented by the process described in relation to FIGS. 5A and 5B may be used in a wide variety of electronic devices and/or systems. For example, the transistor may be used as a switch in a logic circuit, or as part of a storage element in a memory device, such as a dynamic random access memory (DRAM) or a static random access memory (SRAM).

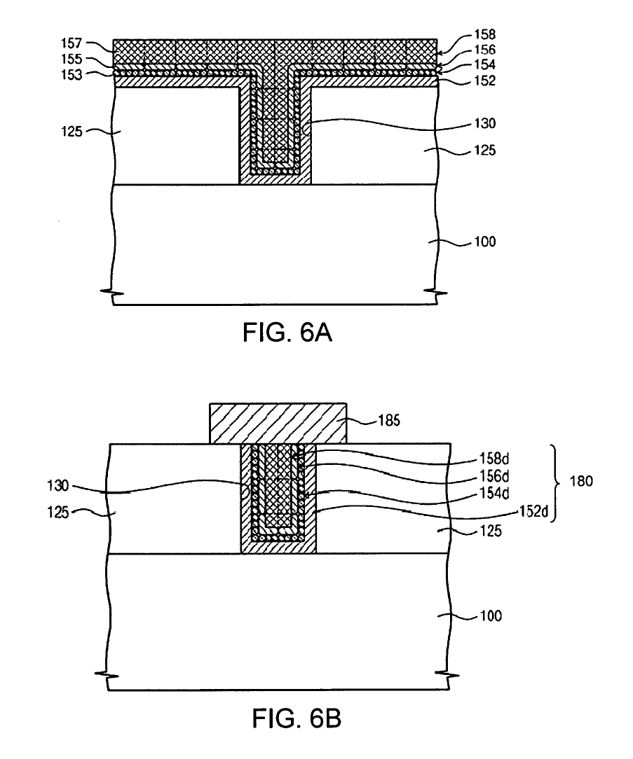

FIGS. 6A and 6B are related schematic diagrams illustrating a conductive structure formed within an opening in a material layer 125. Such openings are commonly used in conjunction with the formation of certain conductive elements, such as metal plugs, contact vias, signal lines, buried contacts, signal redistribution lines, recessed electrodes, damascene structures, etc. More particularly, FIGS. 6A and 6B illustrate an exemplary conductive structure that may serve as contact hole, such as the type commonly used to facilitate electrical connections between elements in a multi-layer device.

In the structures and methods described in FIGS. 6A and 6B, a conductive structure including a bulk metal layer may be formed using processes, materials, and conditions similar to those previously described with reference to FIGS. 1A through 1C, 2A, 2B, 3, 4A through 4D, and/or 5A and 5B.

Referring to FIG. 6A, an insulating layer 125 is formed on substrate 100. Insulating layer 125 is then patterned to form an opening (e.g., a contact hole) 130 exposing substrate 100, or a conductive region formed in substrate 100, or some element (not shown) formed on substrate 100. (In alternate embodiments, opening 130 may be formed in one or more material layer(s) formed on substrate 100, and may not completely penetrate the material layer(s). In such, embodiments, opening 130 will not “expose” a portion of substrate 100 or some structure or region formed on/in substrate 100. Instead, opening 130 may only be formed to a defined depth in the material layer(s), such as insulating layer 125, above substrate 100. Those of ordinary skill in the art will understand such alternatives and the illustrated embodiment of FIG. 6 directed to a contact hole may be readily adapted to support such alternatives.)

Next, conductive layer 152 possibly comprising a metal is formed on insulating layer 125 and on inner surfaces of opening 130. First nucleation layer 154 is then formed on conductive layer 152 using a cyclic deposition process, and second nucleation layer 156 is formed on first nucleation layer 154 using a CVD process. Finally, bulk metal layer 158 is formed on second nucleation layer 156. The formation of conductive structure 180 in this context may completely or partially fill opening 130.

The conductive structure 180 illustrated in FIG. 6B may be used to provide connectivity between stacked features in a multi-layer device or system. However, the illustrated embodiment of FIGS. 6A and 6B should not be construed as being limited as disclosing only the formation of simple contacts. Rather, those skilled in the art will be able to readily extend this example into the fabrication of more complex conductive structures, such as dual damascene structures and other recessed conductive structures.

Returning to FIG. 6B conductive structure 180 is competed by sequentially etching or polishing back portions of bulk metal layer 158, second nucleation layer 156, first nucleation layer 154, and conductive layer 152 outside of opening 130 (e.g., using the upper surface of insulating layer 125 as a etch stop). The resulting conductive structure includes etched bulk metal layer 158d, etched second nucleation layer 156d, etched first nucleation layer 154d, and etched conductive layer 152d. Thereafter, a conductive pattern 185 (e.g., a signal line) may be formed on insulating layer 125 to electrically connect conductive structure 180.

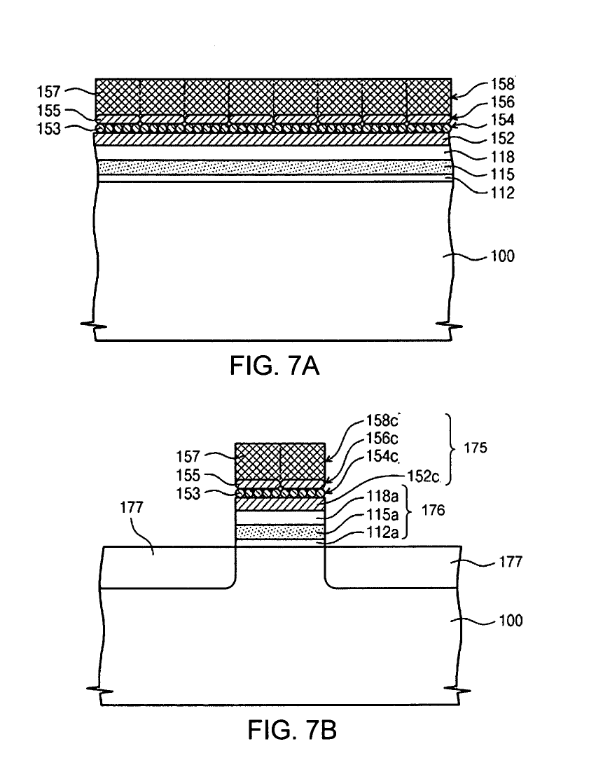

FIGS. 7A and 7B are related diagrams illustrating an exemplary method of forming a conductive structure including a bulk metal layer that may serve as a gate structure including a gate electrode for use within various types of nonvolatile memory. The gate structure may be used, for example, as part of a gate transistor within nonvolatile memory devices, such as floating gate or charge trapping nonvolatile memory devices. General architectures and operating principles for such memories are well known in the art and will not discussed in additional detail here.

Regardless of the specific form and/or operating principles of the incorporating nonvolatile memory device, a gate structure may be implemented with a gate electrode formed from a conductive structure including a bulk metal layer fabricated in accordance with an embodiment of the invention. In other words, any one of the foregoing embodiments may be used to fabricate a transistor gate structure for use within a nonvolatile memory device which benefits from the low resistivity and high material layer uniformity with small geometries afforded by an embodiment of the invention.

Referring to the example illustrated in FIG. 7A, an insulating layer 112 is formed on semiconductor substrate 100. Next, a charge storing layer 115 is formed on insulating layer 112. Thereafter, a blocking insulating layer 118 is formed on charge storing layer 115. Then, conductive layer 152 is formed on blocking insulating layer 118. Next, first nucleation layer 154 is formed on conductive layer 152, second nucleation layer 156 is formed on first nucleation layer 154, and bulk metal layer 158 is formed on second nucleation layer 156 as previously described.

Referring to FIG. 7B, a gate structure including a gate electrode 175 and a charge storing structure 176 forming a general gate transistor within a nonvolatile memory device are formed by sequentially patterning bulk metal layer 158, second nucleation layer 156, first nucleation layer 154, conductive layer 152, blocking insulating layer 118, charge storing layer 115, and insulating layer 112. That is, gate electrode 175 comprises etched bulk metal layer 158c, etched second nucleation layer 156c, etched first nucleation layer 154c, and etched conductive layer 152c. Charge storing structure 176 comprises etched blocking insulating layer 118a, etched charge storing layer 115c, and etched insulating layer 112a. Within charge storing structure 176, etched insulating layer 112a insulates etched charge storing layer 115c which serves as a charge storing element for the gate transistor.

After formation of gate electrode 175 and charge storing structure 176, source/drain regions 177 are selectively formed in substrate 100 using one or more conventional masking and doping processes. Generally speaking, the combination of opposing source/drain regions 177 and the gate structure formed by gate electrode 175 and charge storing structure 176 forms an effective gate transistor operative within a nonvolatile memory device.

Consistent with the former discussion, the sequential patterning of bulk metal layer 158, second nucleation layer 156, first nucleation layer 154, conductive layer 152, blocking insulating layer 118, charge storing layer 115, and insulating layer 112 may be accomplished using a number of conventional processes, including a number of etching processes effectively identified in relation to the specific materials forming each of the foregoing material layers. Associated photolithography and masking processes, as well as intervening cleaning and surface preparation processes will follow from the selection of the desired materials and corresponding etching processes. However, within this selection and application of conventionally understood fabrication processes, the presence of gate electrode 175, as implemented in accordance with an embodiment of the invention, offers the combined benefits of enabling the definition of a gate structure having a small geometry while yet providing acceptable resistivity properties to the gate connection path for the constituent transistor. As the integration density of contemporary nonvolatile memory devices continues to increase, these combined benefits will become increasingly important.

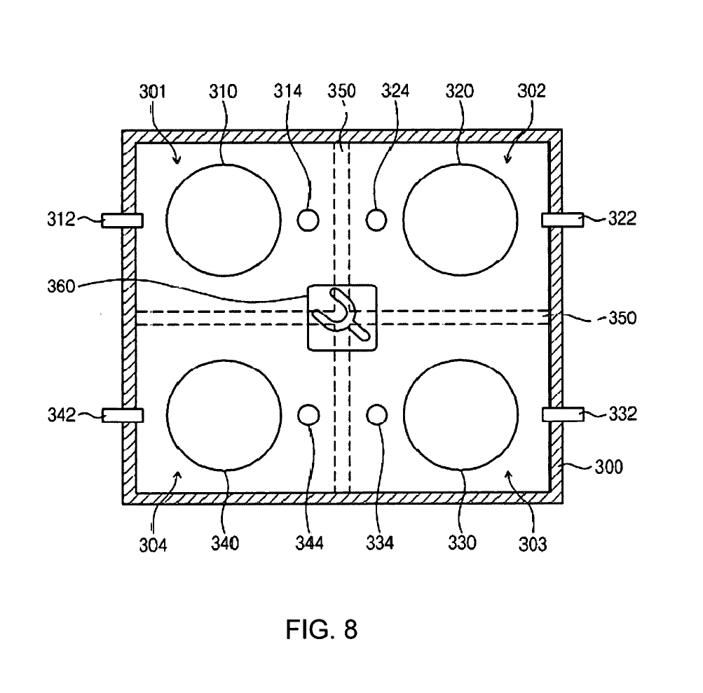

FIG. 8 is an overhead schematic diagram of an exemplary process chamber capable of efficiently fabricating any one of the foregoing conductive structures consistent with an embodiment of the invention. It should be noted, however, that any number of conventionally available process chambers (or sequence of process chambers) may be adapted to run a fabrication sequence capable of implemented an embodiment of the invention. However, the following process chamber arrangement has been found to be particularly efficient in the fabrication of conductive structures including a bulk metal layer consistent with embodiments of the invention.

Referring to FIG. 8, processing chamber 300 is separated into first through fourth process chamber regions 301 through 304 by means of two orthogonally oriented air curtains 350. In the illustrated example, first through fourth process chamber regions 301 through 304 are shown with approximately equal areas, but this need not be the case. Indeed, any reasonable number of process chamber regions of varying size and disposition may be implemented. Further, one or more air curtains of inert gas (e.g., helium, argon, neon, krypton, etc.) may be used to define the size and disposition of the individual process chamber regions within process chamber 300. Alternately or additionally, other separation mechanisms (e.g., walls with air curtain insulated doorways) may be used to segregate the processes being performed in each of the different process chamber regions. This environmental segregation allows different fabrication processes to be run in parallel between the various process chamber regions 301 through 304. In this manner, multiple wafers may be processed within process chamber 300, thereby improving manufacturing throughput.

In the illustrated example, process chamber 300 further comprises a centrally located wafer transfer unit 360. Wafer transfer unit 360 is used to transfer individual wafers or collections of wafers between first through fourth process chamber regions 301 through 304. In this regard, the use of air curtain segregated process chamber regions allows the single, centrally located wafer transfer unit 360 to physically manipulate wafers (or racks of wafers) between the various process chamber regions in a very efficient manner.

First through fourth regions 301 through 304 include first through fourth heater chucks 310, 320, 330, and 340, respectively. The heater chucks are used in a conventional manner to perform various processes within respective process chamber regions. For example, the processes used to form first and the second nucleation layers and the bulk metal layer may be performed at different temperatures and therefore heater chucks 310 through 340 may be used to maintain defined temperatures.

Each one of process chamber regions 301 through 304 also includes corresponding gas supply line(s) and gas discharge line(s). The provision of gas supply and discharge lines may take many different forms within process chamber 300, but in the illustrated example, first through fourth process chamber regions 301 through 304 include respectively associated gas supply lines 312, 322, 332, and 342, and gas discharge lines 314, 324, 334, and 344. Gas supply lines 312 through 342 may include one or more physical gas lines used to supply different gases to first through fourth regions 301 through 304, respectively. Gas discharge lines 314 through 344 may include one or more vents and/or gas evacuation lines respectively arranged around first through fourth regions 301 through 304. Different fabrication processes may be implemented in each process chamber region 310 through 304 by means of these independently operated gas supply and gas discharge lines.

In one specific example, process chamber 300 of FIG. 8 may be used to form the conductive structure including a bulk metal layer as described in relation to the foregoing embodiments. This conductive structure includes bulk metal layer 34 formed on second nucleation layer 33, which is formed on first nucleation layer 32, which is formed on substrate 31.

In this regard, first process chamber region 301 is prepared to run step (401) in the exemplary method illustrated in FIG. 2A or FIG. 3. Following preparation of first process chamber 301 one or more wafers (e.g., silicon substrates on which various semiconductor devices are being fabricated) is loaded onto heater chuck 310. Heater chuck 310 is conventional in its arrangement and operation within process chamber region 301. With the wafer(s) loaded, a sequence of gas applications and gas evacuations is performed under defined conditions that include specific timing requirements, temperature, pressure, etc. For example, where first nucleation layer 32 is formed on a substrate 31 according to the cyclic deposition process (401) described in relation to FIG. 3, a sacrificial gas like silane (SiH₄) is dosed into first process chamber region 301 during a defined dosing period. Then, first process chamber region 301 is purged to remove any residual portion of sacrificial gas (i.e., any un-reacted portion of silane and/or any by-product portion gases) during a first purge period. Following the first purge period, a metal source gas like tungsten hexafluoride (WF₆) is dosed into first process chamber region 301. Following a defined reaction period for the metal source gas, first process chamber region 301 is again purged during a second purge period to remove any residual portion of the metal source gas. This sequence may be repeated until first nucleation layer 32 is formed to a desired thickness on substrate 31.

Once first nucleation layer 32 has been formed, the wafer(s) may be transferred from first process chamber region 301 to another available process chamber region 302 through 304 through air curtain 350. Alternately, the wafer(s) may be retained in first process chamber region 301 for additional processing, or the wafer(s) may be transferred to a holding area outside process chamber 300.

However, in one exemplary embodiment, wafers from first process chamber region 301 having first nucleation layer 32 formed thereon are transferred to second process chamber region 302 through air curtain 350 by wafer transfer unit 360. In second process chamber region 302, second nucleation layer 33 is formed on first nucleation layer 32. As noted above, one or more intervening processes may be performed before second nucleation layer 33 is formed on first nucleation layer 32. Such intervening process(es) may be performed, for example, in third process chamber region 303.

In similar vein, bulk metal layer 34 may be formed on second nucleation layer 33 in fourth process chamber region 304.

As will be appreciated by those skilled in the art, the process conditions in each process chamber region, as well as the corresponding supply and discharge of gases may be controlled by a central control/monitoring system (not shown). Such systems are well known in the field and may be programmed to accomplish a great variety of sequentially and simultaneously performed fabrication processes. In view of the foregoing teachings, adapting such a system to implement a method capable of fabricating a conductive structure consistent with an embodiment of the invention is well within ordinary skill in the art. In one specific implementation embodiment, a process chamber like the one illustrated in FIG. 8 may be controlled by the control/monitoring system to efficiently form one or more conductive structures, as described above.

However fabricated in the context of specific process chamber(s) and/or related equipment, embodiments of the invention provide various conductive structures including a bulk metal layer capable of being implemented with small geometries, yet providing good surface morphology (i.e., highly uniform material nuclei distribution) and improved resistivity characteristics. The foregoing embodiments have described conductive line patterns, contact vias, damascene structures, and gate electrodes for volatile and nonvolatile memory devices as selected examples. However, the scope of the invention is not limited to only these particular conductive structures or the exemplary methods (conditions, materials, etc.) discussed above in relation to these examples. Those skilled in the art will recognize that these are merely teaching examples. Those skilled in the art will further recognize that various modifications may be made to the form and details of these embodiments without departing from the scope of the invention which is defined by the claims that follow.

What is claimed:

1. A method of forming a conductive structure, comprising:
forming a first nucleation layer on a substrate using a cyclic deposition process;
forming a second nucleation layer on the first nucleation layer using a chemical vapor deposition (CVD) process; and
forming a bulk metal layer on the second nucleation layer.

2. The method of claim 1, wherein the bulk metal layer comprises tungsten.

3. The method of claim 1, wherein the bulk metal layer is formed using a CVD process.

4. The method of claim 1, further comprising:
before forming the second nucleation layer, performing one or more plasma treatments on the first nucleation layer.

5. The method of claim 1, wherein the first nucleation layer has a first material grain size and the second nucleation layer has a second material grain size larger than the first grain size.

6. The method of claim 1, wherein a cycle of the cyclic deposition process forming the first nucleation layer comprises:
supplying a sacrificial gas to a process chamber containing the substrate;
performing a first purging process during a first purging period to remove residual sacrificial gas from the process chamber;
following the first purge period, supplying a metal source gas to the process chamber; and
performing a second purging process during a second purging period to remove residual metal source gas from the process chamber.

7. The method of claim 6, wherein the cycle of the cyclic deposition process is repeated until the first nucleation layer is formed to a desired thickness.

8. The method of claim 7, wherein the desired thickness ranges from between about 5 to 50 Å.

9. The method of claim 6, wherein the sacrificial gas comprises boron or silicon.

10. The method of claim 1, further comprising:
before forming the first nucleation layer on the substrate, forming a conductive layer on the substrate, such that the first nucleation layer is formed on the conductive layer; and
successively patterning the bulk metal layer, the second nucleation layer, the first nucleation layer, and the conductive layer to form a metal line pattern.

11. The method of claim 10, wherein the conductive layer comprises at least one material selected from a group of materials consisting of titanium nitride (TiN), tantalum nitride (TaN), tungsten nitride (WN), molybdenum nitride (MoN), niobium nitride (NbN), titanium silicide nitride (TiSiN), tantalum silicide nitride (TaSiN), tungsten silicide (WSix), cobalt silicide (CoSix), nickel silicide (NiSix), cobalt (Co), nickel (Ni), platinum (Pt), gold (Au), Iridium (Yr), or ruthenium (Ru).

12. The method of claim 1, further comprising:
before forming the first nucleation layer on the substrate, forming an insulating layer on the substrate, patterning the insulating layer to form an opening, and forming a conductive layer on the insulating layer and on inner surfaces of the opening;
wherein the first nucleation layer, the second nucleation layer, and the bulk metal layer are sequentially formed on the conductive layer to at least partially fill the opening.

13. The method of claim 11, wherein the opening defines, at least in part, a contact hole, a trench structure, or a damascene structure.

14. A conductive structure, comprising:
a first nucleation layer formed on a substrate and having a first material grain size;
a second nucleation layer formed directly on the first nucleation layer and having a second material grain size larger than the first material grain size; and
a bulk metal layer formed on the second nucleation layer.

15. The conductive structure of claim 14, wherein the bulk metal layer comprises tungsten.

16. The conductive structure of claim 14, further comprising:
an insulation layer formed on the substrate and a conductive layer formed on the insulation layer, such that the first nucleation layer is formed on the conductive layer.

17. The conductive structure of claim 14, further comprising:
an insulation layer having an opening formed therein, wherein the opening is at least partially filled with the combination of the first nucleation layer, the second nucleation layer, and the bulk metal layer.

18. A transistor, comprising:
a gate structure formed on a substrate and opposing source/drain regions formed in the substrate on either side of the gate structure, wherein the gate structure comprises a conductive structure comprising:
a patterned first nucleation layer formed on the substrate and having a first material grain size;
a patterned second nucleation layer having a second material grain size larger than the first material grain size and formed on the patterned first nucleation layer; and
a patterned bulk metal layer formed on the patterned second nucleation layer.

19. The transistor of claim 18, further comprising:
a patterned gate insulating layer formed on the substrate, a patterned polysilicon layer formed on the pattern gated insulating layer, and a patterned conductive layer formed on the patterned polysilicon layer, such that the patterned first nucleation layer is formed on the patterned conductive layer.

20. The transistor of claim 18, further comprising:
a patterned insulating layer formed on the substrate, a patterned charge storing layer formed on the pattern insulating layer, a patterned blocking insulating layer formed on the patterned charge storing layer, and a patterned conductive layer formed on the patterned blocking insulating layer, such that the patterned first nucleation layer is formed on the patterned conductive layer.

21. The transistor of claim 20, wherein the patterned insulating layer is a tunnel insulating layer and the transistor comprises a floating gate transistor.

22. A method of forming a conductive structure on a substrate entirely within a single process chamber comprising a plurality of process chamber regions segregated from one another by at least one air curtain of inert gas, the method comprising:
loading the substrate onto a first heater chuck disposed in a first process chamber region;
forming a first nucleation layer on the substrate by performing a cyclic deposition process in the first process chamber;
transferring the wafer through the air curtain from the first process chamber region to a second heater chuck disposed in a second process chamber region using a wafer transfer unit centrally located in the process chamber;
forming a second nucleation layer on the first nucleation layer by performing a chemical vapor disposition (CVD) process in the second process chamber region; and
forming a bulk metal layer comprising tungsten on the second nucleation layer.

23. The method of claim 22, wherein forming the bulk metal layer on the second nucleation layer comprises:
transferring the wafer through the air curtain from the second process chamber region to a third heater chuck disposed in a third process chamber region using the wafer transfer unit; and
forming the bulk metal layer on the second nucleation layer by performing a CVD process in the third process chamber region.

24. The method of claim 22, wherein each one of the plurality of process chamber regions comprises an independently controllable gas supply line and an independently controllable gas discharge line.
